(19) United States
(12) Patent Application Publication
(10) Pub. No.: US 2002/0145190 A1
(43) Pub. Date: Oct. 10, 2002

(54) Arrangement and method of arrangement of stacked dice in an integrated electronic device

(76) Inventors: Joseph D. Fernandez, Nonthaburi (TH); Ekgachai Kenganatanon, Bangkok (TH); Anucha Suwanpanang, Bangkok (TH); Anucha Phongsantichai, Bangkok (TH)

Correspondence Address: PAUL N. KATZ, BAKER BOTTS L.L.P., ONE SHELL PLAZA, 901 LOUISIANA STREET, HOUSTON, TX, 77002-4995, US

(21) Appl. No.: 09/832,287

(22) Filed: Apr. 10, 2001

(51) Int. Cl. H01L 23/02

(52) U.S. Cl. 257/686

(57) ABSTRACT

An integrated device comprises a lead frame having a plurality of inner leads. Furthermore, a first integrated chip is provided that has a plurality of first bond pads for electronically connecting the chip which is attached to the lead frame. A second integrated chip is provided, being smaller than the first chip, and having a plurality of second bond pads. The second chip is attached on top of the first chip. For interconnection, at least one bond wire connects one of the second bond pads of the second chip with one of the first bond pads of the first chip.

### FIELD OF THE INVENTION

The present invention is related to an arrangement and method of arrangement of stacked dice in an integrated electronic device.

### BACKGROUND OF THE INVENTION TECHNOLOGY

Integrated devices usually comprise a lead frame on top of which an integrated semiconductor chip is mounted. The semiconductor chip comprises a plurality of bond pads which are used to electrically connect the integrated semiconductor chip by means of bonding wires with inner leads of the lead frame. The whole arrangement is then encapsulated and the outer border of the lead frame is cut to separate the different connecting pins which electrically connect the integrated circuits of the chip through the bonding wires with other externally arranged electronic components.

As electronic devices get smaller and smaller highly integrated devices are needed. However, often it is not possible to integrate different electronic components within the same chip as their design require different production technology which sometimes cannot be combined on a single chip. Therefore hybrid solutions are known which use different chips arranged on a supporting substrate. Still, these arrangements require a specific amount of space which often is not available, e.g. in electronic devices such as small remote controls, cell phones, miniature toys, etc.

### SUMMARY OF THE INVENTION

The invention overcomes the above-identified problems as well as other shortcomings and deficiencies of existing technologies by providing an integrated device which requires a minimum of space.

The integrated device may include semi-conductor dice (chips) comprising circuitry manufactured in different technologies.

A method of manufacturing an integrated device requiring less space is also provided.

According to exemplary embodiments of the invention, an integrated device comprising a lead frame having a plurality of inner leads. Furthermore, a first integrated chip is provided that has a plurality of first bond pads for electronically connecting the chip which is attached to the lead frame. A second integrated chip is provided being smaller than the first chip and having a plurality of second bond pads. The second chip is attached on top of the first chip. For interconnection, at least one bond wire connects one of the second bond pads of the second chip with one of the first bond pads of the first chip.

In another exemplary embodiment at least one bond wire connects one of the second bond pads with one of the first bond pads and with one of the inner leads.

In yet another exemplary embodiment each pad of the second bond pads which is to be connected to a pad of the first bond pads has a location on the second chip which is in relation approximately similar to the location of the pad on the first chip.

The integrated chips can be standard semiconductor chips comprising different or equal manufacture technology or can be any kind of hybrid chips comprising different technology combined on one supporting substrate.

In another exemplary embodiment a method of arranging an integrated device comprises the steps of

providing a lead frame having a plurality of inner leads;

providing a first integrated chip having a plurality of first bond pads for electronically connecting said chip attached to said lead frame;

providing a second integrated chip being smaller than said first chip having a plurality of second bond pads and being attached on top of said first chip; and

connecting one of said second bond pads of said second chip with one of said first bond pads of said first chip by means of at least one bond wire.

The arrangement and method according to exemplary embodiments of the present invention avoids the obstacle if the bonding pads of two chips that are arranged within the same housing have to be connected to the same inner lead. Those traditional arrangements can make it difficult for the operator to sequence the wire bonding process, e.g., which pad opening/wire needs to be wirebonded first and which pad/wire needs to be bonded in sequence to the same inner lead. This causes wire deformation due to wrong bonding sequence in which the capillary tool will have the tendency to hit the adjacent wire that is bonded while creating a wireloop profile.

### BRIEF DESCRIPTION OF THE DRAWINGS

FIG. 1 shows a top view of an arrangement according to exemplary embodiments of the present invention,

FIG. 2 shows a side view of an arrangement according to exemplary embodiments of the present invention,

FIGS. 3A and 3B show sections of different exemplary embodiments of the present invention,

FIG. 4 shows a side view of yet another exemplary embodiment of the present invention, and

FIG. 5 shows a perspective view of an arrangement similar to the one shown in FIG. 1.

While the present invention is susceptible to various modifications and alternative forms, specific exemplary embodiments thereof have been shown by way of example in the drawing and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

FIG. 1 shows a top view of one exemplary embodiment of the present invention. A lead frame 110 comprises a supporting structure 113 and a connecting portion consisting of inner leads 112 and external connecting pins or terminals 111. On top of the supporting structure 113 is mounted a first chip or die 120 by means of epoxy resin or any other suitable glue. The chip 120 can be a semiconductor chip, a hybrid chip comprising integrated and discrete components or any other electronic component. The chip 120 comprises a plurality of bond pads 121 which in the shown embodiment are located along opposite sides of the chip 120. These pads 121 serve to interconnect the different circuits of the chip 120 with external components via the leads of the lead frame 110. A second chip or die 130 which is smaller in size than the first chip 120 is mounted on top of the first chip 120 using epoxy resin or any other suitable glue. The glue must not only provide secure attachment but also electrical insulation between the two chips 120, 130. The second chip 130 also provides bond pads which are preferably arranged in a similar manner than those of the first chip 120. The size of the second chip 130 is smaller than that of the first chip 120 to provide access to the bond pads 121 of the first chip. Preferably, as the epoxy spreads after attaching the upper chip 130 a clearance of 30 mils to all sides can be provided. This is also preferred in particular if all four sides of the first chip provide bond pads.

Furthermore, it is preferred that the function or the electrical output signals of the bond pads of the two chips 120, 130 is as far as possible similar. In other words, the bond pad for the supply voltage Vcc of both chips 120, 130 should in relation be arranged at the same location, e.g. the top left bond pad as shown in FIG. 1. Any pads of the first and second chip 120, 130 which have to be interconnected are preferably arranged such that their relative location on the chip is similar. In particular this ensures that no overcrossing of bond wires occurs as it is shown in FIG. 1.

The bond wire process, for example a gold wire bonding process, is preferably performed from the pad opening of the top chip 130 to the pad opening of the bottom chip 120. In addition, if both interconnected bond pads need to be connected to a respective lead of the lead frame an additional step is added and the bond wire is hooked up to the respective inner lead of the leadframe.

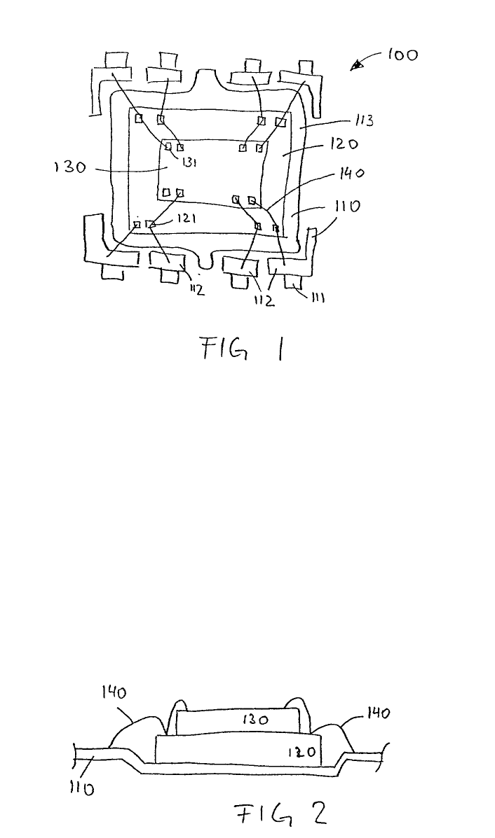

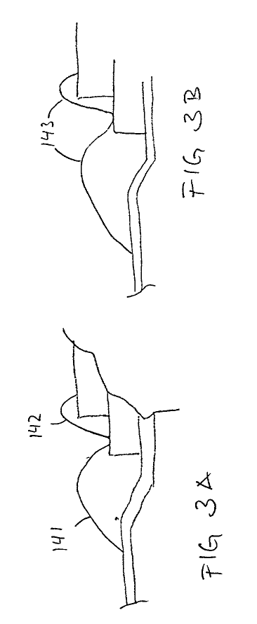

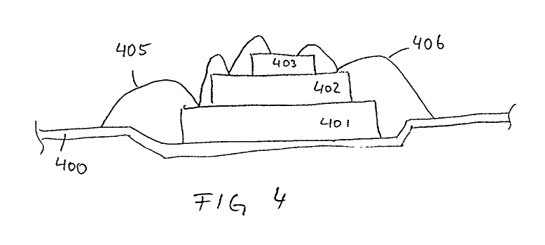

FIG. 2 shows in particular such a connection. The bond wire 140 connects the respective bond pad of the upper chip 130 with the respective one of the lower chip 120 and with a respective lead of the leadframe. FIGS. 3A and 3B show different ways to perform such a serial connection. In a first embodiment shown in FIG. 3A two separate wires 141 and 142 are used to establish the interconnection. For example, the capillary tool which carries the gold wire first connects one end of the gold wire to a bond pad on the upper chip 130, then moves the wire of the bond pad of the lower chip 120. A second wire will then be used to connect the bond pad of the lower chip 120 with a lead of the leadframe. This can be done in a suitable sequence to provide a fast bonding process.

In another exemplary embodiment this process is facilitated. Instead of cutting the gold wire after the first connection, as shown in FIG. 3A, the capillary tool after bonding the wire to the respective pad of the first chip 120 moves to the respective inner lead of the leadframe and thus interconnects both bond pads of the upper chip 130 and the lower chip 120 with the respective inner lead of leadframe 110. This also speeds up the manufacturing process and avoids problems with any interconnection.

To ensure that the overall size requirement of the electronic device is met there is a need to control the die thickness of the chips 120, 130. Also, the die thickness shall be determined for both dices to ensure wires are not exposed out of an encapsulated package.

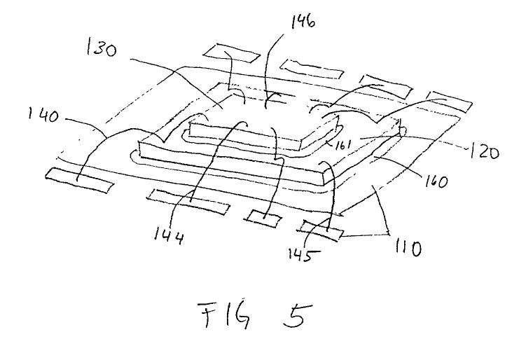

FIG. 4 shows a further exemplary embodiment of the present invention in which a third chip 403 smaller in size than the second chip 402 is mounted on top of the second chip 402 which again is mounted on top of a first chip 401. This stacked arrangement is again mounted to a leadframe 400 which supports the structure. Again, bond wires 405, 406 can connect bond pads of all three chips 401, 402, and 403 with a lead of lead frame 400 or one or more chips. Of course, interconnections of pads of the chips without connecting to one of the leads is also possible as any other variety. The present invention is of course not limited to stacks of to or three chips and can be extended as needed and allowed by the respective design.

FIG. 5 shows a perspective view of an arrangement similar to the one shown in FIG. 1. This figure shows also different varieties of interconnections. For example, wire 140 connects a lead with pads of chip 120 and of chip 130. Wire 144 only connects a pad of chip 130 with a lead. Wire 145 only connects a pad of chip 120 with a lead and wire 146 only interconnects a pad of chip 120 with a pad of chip 130. Furthermore the epoxy resin 160 is shown which attaches chip 120 to the leadframe and the epoxy resin 161 which attaches chip 130 to chip 120 are depicted.

The invention, therefore, is well adapted to carry out the objects and attain the ends and advantages mentioned, as well as others inherent therein. While the invention has been depicted, described, and is defined by reference to exemplary embodiments of the invention, such references do not imply a limitation on the invention, and no such limitation is to be inferred. The invention is capable of considerable modification, alternation, and equivalents in form and function, as will occur to those ordinarily skilled in the pertinent arts and having the benefit of this disclosure. The depicted and described embodiments of the invention are exemplary only, and are not exhaustive of the scope of the invention Consequently, the invention is intended to be limited only by the spirit and scope of the appended claims, giving fill cognizance to equivalents in all respects.

What is claimed is:

1. An integrated device, comprising:
a lead frame having a plurality of inner leads;
a first integrated chip having a plurality of first bond pads for electronically connecting said chip attached to said lead frame;
a second integrated chip being smaller than said first chip having a plurality of second bond pads and being attached on top of said first chip; and
at least one bond wire connecting one of said second bond pads of said second chip with one of said first bond pads of said first chip.

2. The integrated device according to claim 1, further comprising at least one bond wire connecting one of said second bond pads with one of said first bond pads and with one of said inner leads.

3. The integrated device according to claim 1, wherein each pad of said second bond pads which is to be connected to a pad of said first bond pads has a location on said second chip which is in relation approximately similar to the location of said pad on said first chip.

4. The integrated device according to claim 1, further comprising at least one further bond wire connecting said one bond pad of said first chip with a inner lead of said lead frame.

5. The integrated device according to claim 1, wherein said second chip is attached to said first chip by means of Epoxy resin.

6. The integrated device according to claim 1, further comprising at least a further integrated chip being smaller than said second chip attached on top of said second chip and having a plurality of third bond pads.

7. The integrated device according to claim 6, further comprising at least one further bond wire connecting one of said third bond pads with one pad out of the group of first and second pads.

8. The integrated device according to claim 1, wherein said second chip has a size and is mounted on top of said first chip to define a predefined clearance to all four sides of said first chip.

9. The integrated device according to claim 1, wherein said first chip comprises a microcontroller and said second chip comprises a radio frequency circuit.

10. A stacked arrangement of semiconductor chips, comprising:
a lead frame having a plurality of inner leads;
a first semiconductor chip having a plurality of first bond pads for electronically connecting said chip attached to said lead frame;
a second semiconductor chip being smaller than said first chip having a plurality of second bond pads and being attached on top of said first chip; and
at least one bond wire connecting one of said second bond pads of said second chip with one of said first bond pads of said first chip.

11. The stacked arrangement according to claim 10, further comprising at least one bond wire connecting one of said second bond pads with one of said first bond pads and with one of said inner leads.

12. The stacked arrangement according to claim 10, wherein each pad of said second bond pads which is to be connected to a pad of said first bond pads has a location on said second chip which is in relation approximately similar to the location of said pad on said first chip.

13. The stacked arrangement according to claim 10, further comprising at least one further bond wire connecting said one bond pad of said first chip with a inner lead of said lead frame.

14. The stacked arrangement according to claim 10, wherein said second chip is attached to said first chip by means of Epoxy resin.

15. The stacked arrangement according to claim 10, further comprising at least a further integrated chip being smaller than said second chip attached on top of said second chip and having a plurality of third bond pads.

16. The stacked arrangement according to claim 15, further comprising at least one further bond wire connecting one of said third bond pads with one pad out of the group of first and second pads.

17. The stacked arrangement according to claim 10, wherein said second chip has a size and is mounted on top of said first chip to define a predefined clearance to all four sides of said first chip.

18. The stacked arrangement according to claim 10, wherein said first chip comprises a microcontroller and said second chip comprises a radio frequency circuit.

19. A method of arranging an integrated device comprising the steps of:
providing a lead frame having a plurality of inner leads;
providing a first integrated chip having a plurality of first bond pads for electronically connecting said chip attached to said lead frame;
providing a second integrated chip being smaller than said first chip having a plurality of second bond pads and being attached on top of said first chip; and
connecting one of said second bond pads of said second chip with one of said first bond pads of said first chip by means of at least one bond wire.

20. The method according to claim 19, further comprising the step of connecting one of said second bond pads with one of said first bond pads and with one of said inner leads by means of at least one single bond wire.

21. The method according to claim 20, wherein said bonding starts at one of the second bond pads and ends at one of said inner leads.

22. The method according to claim 19, wherein said second chip is attached to said first chip using epoxy resin.
